(19) United States
(12) Patent Application Publication
(10) Pub. No.: US 2003/0038297 A1
(43) Pub. Date: Feb. 27, 2003

(54) Apparatus,system, and method for transmission of information between microelectronic devices

(76) Inventors: Robert Carroll, Andover, MA (US); William Pohlman, Phoenix, AZ (US); Jonathan McFarland, Phoenix, AZ (US); Kannan Raj, Chandler, AZ (US); Suresh Golwalkar, Phoenix, AZ (US); Wuchun Chou, Chandler, AZ (US); C. Phillip McClay, Fountain Hills, AZ (US)

Correspondence Address: SNELL & WILMER, ONE ARIZONA CENTER, 400 EAST VAN BUREN, PHOENIX, AZ, 850040001

(21) Appl. No.: 10/236,353

(22) Filed: Sep. 5, 2002

Related U.S. Application Data
(63) Continuation-in-part of application No. 10/104,942, filed on Mar. 22, 2002.
(63) Continuation-in-part of application No. 10/055,679, filed on Jan. 22, 2002.
(63) Continuation-in-part of application No. 09/911,918, filed on Jul. 24, 2001.
(63) Continuation-in-part of application No. 10/056,757, filed on Jan. 23, 2002.
(60) Provisional application No. 60/356,806, filed on Feb. 13, 2002.
(60) Provisional application No. 60/356,808, filed on Feb. 13, 2002.

(51) Int. Cl. H01L 33/00

(52) U.S. Cl. 257/99

(57) ABSTRACT

A system for transmitting information between a plurality of microelectronic devices is disclosed. The system includes a plurality of microelectronic devices coupled to an interconnect, which may be optical or electrical. The system may further include one or more switches to transfer information between the various microelectronic devices.

### CROSS REFERENCE TO RELATED APPLICATIONS

This Application claims priority to application Ser. No. 10/104,942, entitled HIGH SPEED OPTICAL TRANSCEIVER ARRAY ON COMPACT CHIP CARRIER WITH INTEGRATED FIBERS ON V-GROOVES, filed Mar. 22, 2002; application Ser. No. 10/055,679, entitled OPTICAL INTERCONNECT WITH INTEGRAL REFLECTIVE SURFACE AND LENS, SYSTEM INCLUDING THE INTERCONNECT AND METHOD OF FORMING THE SAME, filed Jan. 22, 2002; application Ser. No. 09/911,918, entitled APPARATUS FOR COUPLING A FIBER OPTIC CABLE TO AN OPTOELECTRONIC DEVICE, A SYSTEM INCLUDING THE APPARATUS, AND A METHOD OF FORMING THE SAME, filed Jul. 24, 2001; application Ser. No. 10/056,757, entitled APPARATUS FOR COUPLING AN OPTOELECTRONIC DEVICE TO A FIBER OPTIC CABLE AND A MICROELECTRONIC DEVICE, A SYSTEM INCLUDING THE APPARATUS, AND A METHOD OF FORMING THE SAME, filed Jan. 23, 2002; Provisional Application Serial No. 60/356,806, entitled CURRENT SOURCE OUTPUT LIGHT EMITTING DEVICES DRIVER, filed Feb. 13, 2002; and to Provisional Application Serial No. 60/356,808, entitled SELF-BIASING TRANSIMPEDANCE AMPLIFIER, filed Feb. 13, 2002.

### FIELD OF THE INVENTION

The present invention generally relates to devices and systems for transmitting signals between a plurality of microelectronic devices. More particularly, the invention relates to bus structures, systems, and schemes for transmitting the signals.

### BACKGROUND OF THE INVENTION

Electrical bus structures are typically employed to transmit information between various microelectronic integrated circuits such as microprocessors, microcontrollers, and memory circuits. For example, electrical bus systems are used in computing systems to transmit information between a microprocessor and a memory circuit. Electrical busses are often used because they are relatively inexpensive compared to optical bus systems and because the architecture required to transmit information using electrical busses is relatively well developed.

Typical computing systems use a parallel bus, including a plurality of lines, to transmit the information between the integrated circuits. As the amount of information transmitted between the circuits increases (e.g., resulting from increased operational speed of a microelectronic device and/or addition of microelectronic devices to a system), the number of lines of the bus system and the clock speed of the data transmission generally increase.

As the rate of data transfer between microelectronic devices increases, use of typical electrical bus schemes to transmit the information becomes increasingly problematic. In particular, as the amount of information transfer increases, an amount of input/output power required to transmit information between devices and consequently an amount of electronic noise associated with the transmission increase. The noise resulting from the additional input/output power requirement often results in signal integrity problems with the information transmitted between the devices. High input/output power requirements also generally require more on-chip charge storage. The additional charge storage requirements generally result in higher device costs because of reduced yield, increased device size, and increased device manufacturing complexity. Further, the increased input/output current and increased transmission rate can detrimentally affect performance of power regulators coupled to the devices. In addition, the increased current and rate of the transmitted information generates increased electromagnetic interference (EMI), which may require additional shielding and thus increases the cost of systems using the parallel electronic bus system.

Another problem associated with transmission of electrical signals using traditional electrical bus systems is that signal degradation increases as the rate of the transmitted signal increases. For example, when signals are transmitted at a rate of about 5 GHz using FR-4 substrate material, the signal suffers about a 60 dB loss across 10 cm. This loss can cause risetime degradation and amplitude loss for the signals as the higher order harmonics are filtered out. Accordingly, improved apparatus and systems for transmitting information between a plurality of microelectronic devices is desired.

### SUMMARY OF THE INVENTION

The present invention provides improved methods and apparatus for transmitting information between a plurality of microelectronic devices. More particularly, the invention provides a method and apparatus for transmitting high-speed, high bandwidth information between a plurality of microelectronic devices.

The way in which the present invention addresses various drawbacks of the now known parallel electrical data transmission systems is discussed in greater detail below. However, in general, the improved information transmission apparatus and system provide high bandwidth communication, with lower EMI and better signal integrity than traditional systems.

In accordance with one embodiment of the present invention, a data transmission system includes a device to multiplex electrical signals, a device to convert the electrical signals to optical signals, and an optical waveguide. In accordance with one aspect of this embodiment of the invention, the system also includes a device to convert optical signals to electrical signals and a device to demultiplex converted electronic information. In accordance with another aspect of this embodiment, the system also includes a device to multiplex a plurality of optical signals for transmitting the plurality of signals using a signal waveguide and/or to demultiplex a plurality of optical signals for conversion to electrical signals. The optical signals may be transmitted using serial or parallel paths using single or multiple wavelengths of light.

In accordance with various embodiments of the invention, the devices that convert electrical signals to optical signals and/or the devices that convert optical signals to electrical signals are placed proximate the microelectronic device. In accordance with one embodiment of the invention, an optoelectronic device and the microelectronic device are coupled to the same surface of a substrate. In accordance with another embodiment of the invention, the optoelectronic device and the microelectronic device are coupled to different surfaces of the substrate. In accordance with yet another embodiment of the invention, the optoelectronic device is embedded within a substrate coupled to the microelectronic device. And, in accordance with yet another embodiment of the invention, the optoelectronic device and the microelectronic devices are attached to separate substrates and the separate substrates are coupled together using a third substrate.

In accordance with various additional embodiments of the invention, a data transmission system includes a plurality of microelectronic devices coupled to a switch configured to route information between the microelectronic devices. In accordance with one aspect of this embodiment, the switch is configured to route optical signals, and in accordance with another aspect, the switch is configured to route electrical signals.

### BRIEF DESCRIPTION OF THE DRAWINGS

A more complete understanding of the present invention may be derived by referring to the detailed description and claims, considered in connection with the figures, wherein like reference numbers refer to similar elements throughout the figures, and:

FIG. 1 is a schematic illustration of a portion of an information transmission system in accordance with an exemplary embodiment of the invention;

FIG. 2 is a schematic illustration of a portion of an information transmission system in accordance with another exemplary embodiment of the invention;

FIGS. 3-6 illustrate information transmission systems in accordance with various additional embodiments of the invention;

FIGS. 7-12 illustrate yet additional information transmission systems in accordance with the present invention; and

FIGS. 13-14 illustrate information transmission systems including switches to route information, in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF EXEMPLARY EMBODIMENTS

The present invention generally relates to devices and systems for transmitting information between a plurality of microelectronic devices. More particularly, the invention relates to structures, assemblies, and systems for optically transmitting data, using serial or parallel techniques, or electrically transmitting information using serial transmission techniques. Although the systems of the present invention may be used to transmit information between various types of electronic circuits, the invention is conveniently described below in connection with transmitting information between a microprocessor and another microelectronic device. The transmission distances ideally utilizing this invention are in the range of a few millimeters to 300 meters or more.

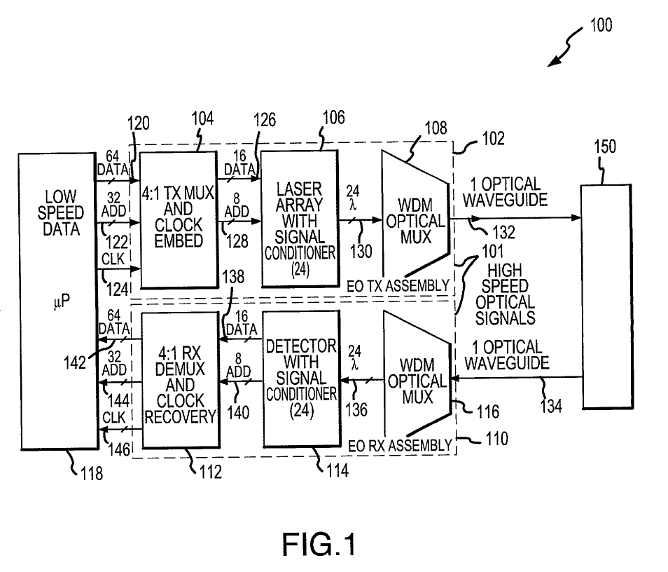

FIG. 1 schematically illustrates a portion 100 of a system for transmitting information between microelectronic devises, wherein at least a portion of a transmission path between the devices includes an optical waveguide such as an optical fiber. System 100 includes an optical sub assembly 101, which includes a transmit portion 102 configured to convert electrical signals to optical signals for transmission of information to another device 150 and a receive portion 110 configured to convert optical signals to electrical signals for transmission of information to microprocessor 118. In the illustrated embodiment, transmit portion 102 includes a multiplexing circuit 104, an optoelectronic device array 106, and an optical multiplexing device 108 and receive portion 110 includes a demultiplexing circuit 112, an optoelectronic device array 114, and an optical demultiplexing device 116. Although illustrated with both transmission and receive portions, systems in accordance with the present invention may include only a transmission portion or only a receive portion.

In operation, electrical information from microprocessor 118 is converted to optical information at portion 102 for transmission via waveguide 132 to another microelectronic device 150 and optical information is received at portion 110 via waveguide 134, where it is converted to electrical information for transmission to microprocessor 118. More specifically, electrical information from microprocessor 118 is transmitted to multiplexing circuit 104 over data lines 120, address lines 122, and clock line 124. At multiplexing circuit 104, the information is multiplexed for transmission of data and address information, over a fewer number of data lines 126 and address lines 128, to array 106. At array 106, electronic information is converted to optical information for transmission using lines 130 to optical multiplexing device 108. Multiplexing device 108 multiplexes the optical information for transmission over waveguide 132 to another microelectronic device 150. Similarly, multiplexed optical information transmitted to microprocessor 118 is received at demultiplexing device 116 over guide 134 and is transmitted to optoelectronic array 114 over a greater number of lines 136. Optoelectronic array 114 converts the optical information to electrical information for transmission over data lines 138 and address lines 140 to demultiplexing circuit 112. At circuit 112, the information is demultiplexed for transmission over data lines 142, address lines 144, and clock line 146. In the illustrated example, microprocessor 118 transmits on N parallel paths to optical subassembly 102, N being equal to 96 (the sum of 64 data and 32 address paths). Multiplexing device 108 is illustrated with a reduction factor K=4:1. Thus, the parallel paths from multiplexing device 104 to laser array 106 have been reduced to 24 (the sum of 16 data and 8 address paths). Optical multiplex device 108 is illustrated with a reduction factor of 24:1, such that its ouput can be sent to the other microelectronic device 150 on a single optical waveguide 132. The illustrated example further shows information received from device 150 on a single optical waveguide 134. Demultiplexing device 116 converts to 24 parallel paths to detector 114; which converts the optical to electrical signals providing 24 parallel inputs to demultiplexing device 112; which in turn provides 96 parallel paths (64 data+32 address) to microprocessor 118. Although exemplary system 100 is illustrated with 4:1 multiplexing at circuit 104, 24:1 multiplexing at device 108, 4:1 demultiplexing at circuit 112, and a specific number of data transmission lines between the various components, any suitable degree of multiplexing, demultiplexing, number of data line, address lines, and clock lines can be used to transmit information using systems of the present invention. Further, either serial or parallel information, which is synchronized or asynchronous may be transmitted between microelectronic devices using the systems of the present invention.

Multiplexing circuit 104 and demultiplexing circuit 112 may comprise any suitable circuit, e.g., frequency-division multiplexing or time-division multiplexing circuits. In accordance with an exemplary embodiment of the invention, multiplexing circuit 104 and demultiplexing circuit 112 include embedded clock and clock recover capabilities, respectively. Circuits 104 and 112 may also include forward error correction coding to reduce bit errors in the transmitted information. In accordance with an alternate embodiment of the invention, portions of the multiplexing, demultiplexing, clock embedding and/or clock recovery functions may be performed by microprocessor 118. In this case, fewer input/output ports are required on microprocessor 118 to transmit a given amount of information.

Array 106 includes one or more light emitting devices and system 100 also includes a suitable driver circuit proximate the array. In accordance with one embodiment of the invention, each light emitting device is a vertical cavity surface emitting laser (VCSEL) and the corresponding driver provides suitable current to drive the VCSEL, and may include additional features such as temperature compensation and the like.

Optical multiplexing device 108 and demultiplexing device 116 may include any components that perform the appropriate multiplexing or demultiplexing function, e.g., using wavelength-division multiplexing (WDM) or dense wavelength division multiplexing (DWDM) and demultiplexing technology. For example, device 108 may include arrayed waveguide grating and device 116 may include arrayed waveguide grating. Although illustrated as using separate paths for multiplexing and demultiplexing information, a signal path may be used for both functions; however, using two paths as illustrated allows for an increased amount of information transfer.

Optical waveguides 132 and 134 of system 100 may include any medium suitable for transferring light emitted from or received by devices 108 and 116. Because information is multiplexed before transmission across guide 132 and demultiplexed when received form guide 134, a reduced number of waveguides are required to transmit the information.

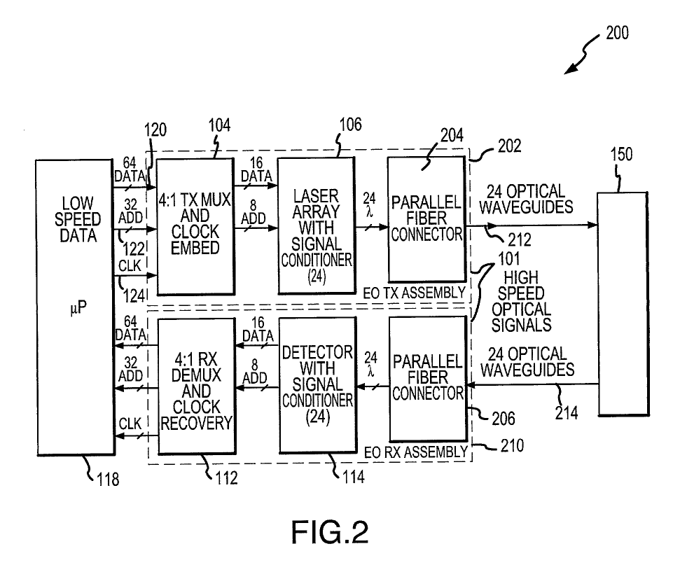

FIG. 2 illustrates another system portion 200 in accordance with the present invention. Similar to system 100, system 200 includes an optical assembly 201, including a signal transmission portion 202 and a signal receive portion 210 coupled to microprocessor 118. Transmission portion 202 includes multiplexing circuit 104 and optoelectronic array 106 as described above and also includes a waveguide connector 204 and optical wave guides 212 for transmitting optical signals to another microelectronic device 150. Receive portion 210 receives optical signals from another microelectronic device 150 via wave guide 214 and includes a demultiplexing circuit 112 and a optoelectronic array 114 as described above and a waveguide connector 206. Connectors 204 and 206 may be formed in a variety of ways, and are preferably formed such that waveguides 212 and 214 line up with input or output regions of array 106 or 114. Exemplary connectors are described in detail in application Ser. No. 10/056,757, entitled APPARATUS FOR COUPLING AN OPTOELECTRONIC DEVICE TO A FIBER OPTIC CABLE AND A MICROELECTRONIC DEVICE, A SYSTEM INCLUDING THE APPARATUS, AND A METHOD OF FORMING THE SAME and filed Jan. 23, 2002, the contents of which are hereby incorporated herein by reference.

System 200 operates in a manner similar to system 100, except that optical signals are not multiplexed or demultiplexed. Thus, a plurality of light emitting devices within array 106 are coupled to a plurality of waveguides 212—e.g., individual optical fibers, and a plurality of waveguides 214 are coupled to a plurality of light detecting devices within array 114.

In accordance with additional embodiments of the invention, electrical information is transmitted between a plurality of microelectronic devices using serial processing techniques. In this case, the systems do not require the optoelectronic devices and corresponding circuits described above, and the optical waveguide is replaced with an electrically conductive bus. The serial signaling allows multiple transmit and receive circuits to be placed in parallel to facilitate scaling of the system.

In accordance with various aspects of this embodiment of the invention, the transmit and receive components are placed proximate microprocessor 118—e.g., on the same package as microprocessor 118 or on the same board as the microprocessor (either on the same or opposing side) to reduce the amount of energy required by microprocessor 118 I/O drivers. The transmit and receive circuit signal is preferably compatible with a one or more transmission media such as stripline, microstrip, coaxial cable, and optical fiber. At the contemplated frequencies, the connections between the transmit and receive components are essentially microwave transmission lines. When stripline, microstrip, or coaxial cable are employed, differential signaling with matched impedance drivers and receivers may be used to increase the bandwidth of transmitted information and reduce noise and interconnect parasitics.

Use of serial optical transmission, rather than traditional parallel electrical transmission, of information is advantageous because it allows for higher bandwidth information transmission with fewer interconnections between microelectronic devices. In addition, less EMI is produced using the serial system and thus less shielding is required for such system. Moreover, an optical transmission system generates no EMI permitting even higher bandwidth transmission with parallel optical transmission.

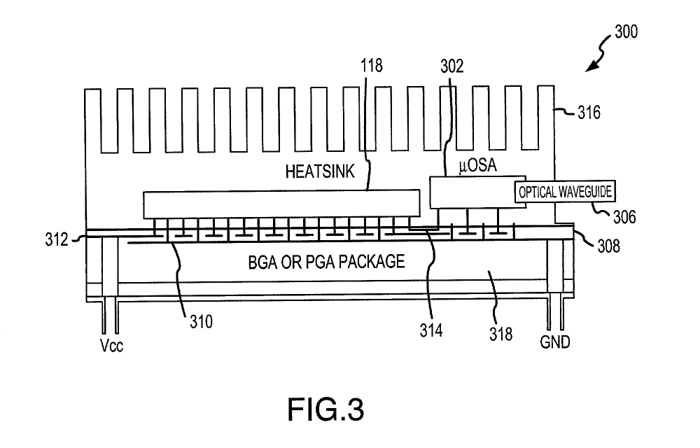

FIGS. 3-12 illustrate various configurations for packaging information transmission systems in accordance with various exemplary embodiments of the invention, such as systems 100 and 200. In general, each system includes at least one optical assembly to convert information between optical and electrical data, as described above, coupled to a microelectronic device. The optical sub assembly and microprocessor are coupled proximate each other to reduce a distance signals need to travel between the devices, which in turn, reduces an amount of energy required to transmit the signals and allows for higher speed transmission.

System 300, illustrated in FIG. 3, includes a microelectronic device and optoelectronic components coupled to the same surface of a substrate. System 300 includes microprocessor 118, electrically coupled to an optical sub assembly 302, which is optically coupled to a waveguide 306. Optical sub assembly 302 may include either of assemblies 101 or 201 or portions (e.g., receive portion or transmit portion) thereof. System 300 optionally includes a heat sink 316 to facilitate heat transfer away from processor 118 and/or assembly 302 and a package 318 such as a ball grid array or pin grid array package.

In accordance with the illustrated embodiment of the invention, optical sub assembly 302 includes at least one optoelectronic device and a corresponding microelectronic device. For example, optical sub assembly 302 may include a plurality of light detecting devices and a corresponding amplifier, a plurality of light emitting devices and a corresponding driver, or any suitable devices that convert information between optical and electrical formats. Exemplary sub assemblies suitable for use with the present invention are illustrated in application Ser. No. 10/104,942, entitled OPTICAL INTERCONNECT STRUCTURE, SYSTEM AND TRANSCEIVER INCLUDING THE STRUCTURE, AND METHOD OF FORMING THE SAME, and filed Mar. 22, 2001, the contents of which are hereby incorporated herein by reference.

Microprocessor 118 and sub assembly 302 may be coupled to a substrate 308 in a variety of ways. For example, sub assembly 302 and/or microprocessor 118 may be coupled to substrate 308 using wire bond techniques. In accordance with one embodiment of the invention, microprocessor 118 and sub assembly 302 are coupled to substrate 308 using flip-chip techniques such as Controlled Collapsed Chip Connection (“C4”) techniques.

Substrate 308 may be formed of any suitable material. For example, in accordance with one embodiment of the invention, substrate 308 is formed of fire-retardant printed circuit board material such as FR-4.

Substrate 308 includes suitable electrical connections such as conductive traces 310 and 312, coupled to ground and Vcc respectively, to provide operating power to both sub assembly 302 and processor 118. In addition, substrate 308 includes conductive traces 314 to electrically couple processor 18 and assembly 302 and allow information transfer between assembly 302 and processor 118.

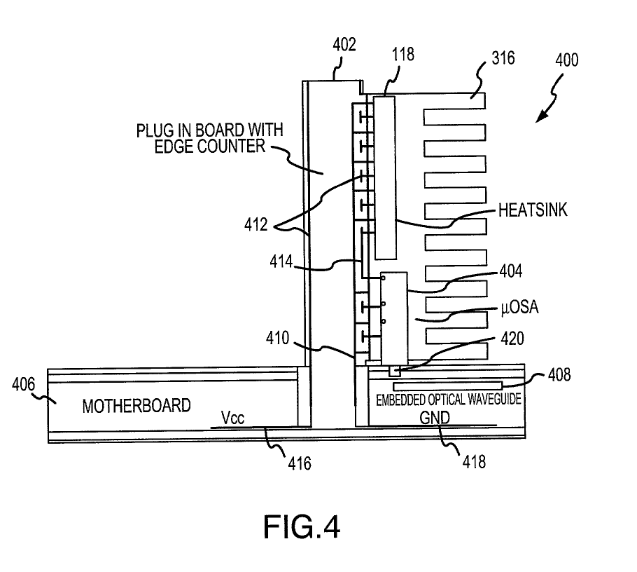

FIG. 4 illustrates another system 400, including a microelectronic device and an optical sub assembly coupled to a first substrate, which is plugged into a second substrate. System 400 includes a first substrate 402, having microprocessor 118 and an optical sub assembly 404 coupled to substrates 402, and a second substrate 406 configured to receive one or more substrate(s) 402 and having an optical waveguide 408 to facilitate optical communication between a plurality of microelectronic devices.

Similar to substrate 308, substrate 402 includes electrical connections such as conductive traces 410, 412, and 414 to electrically couple processor 118 and assembly 404 to ground, Vcc, and each other, respectively. In accordance with one aspect of this embodiment of the invention, substrate 402 is a plug-in board with edge connectors configured to plug into substrate 406.

Substrate 406, e.g., a motherboard of a computing system, includes an electrical connection 416 to a Vcc supply and an electrical connection 418 to ground, and may include additional electrical connection to couple processor 118 to other microelectronic devices coupled to substrate 406 and/or to couple other microelectronic devices to each other. Substrate 406 also includes waveguide 408. In accordance with the illustrated embodiment, guide 408 is formed within substrate 406; however, guide 408 may also be formed on a surface of substrate 402 in accordance with the present invention. Guide 408 may be formed of a variety of materials, such as layers of silicon oxide, optical fibers, and the like.

Optical interconnection between assembly 404, and in particular, guide 420 of assembly 404 and guide 408 may be formed in a variety of ways. For example, guide 420 and guide 408 may be optically coupled by forming a reflective surface within substrate 406 to guide light between guides 420 and 408. Additional exemplary techniques for coupling guides 420 and 408 are illustrate in application Ser. No. 10/055,679, entitled OPTICAL INTERCONNECT WITH INTEGRAL REFLECTIVE SURFACE AND LENS, SYSTEM INCLUDING THE INTERCONNECT AND METHOD OF FORMING THE SAME, and filed Jan. 22, 2002, the contents of which are hereby incorporated herein by reference.

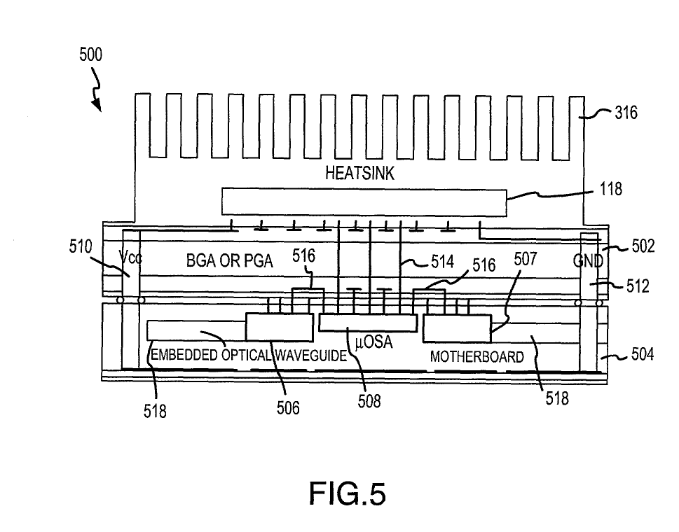

FIG. 5 illustrates a system 500, including a first substrate 502 having microprocessor 118 attached thereto and a second substrate 504 having optoelectronic devices 506, 507 and a corresponding circuit 508. In the illustrated example, devices 506, 507 and circuit 508 are embedded within substrate 504. In accordance with alternate aspects of this embodiment, the devices and/or circuits may be coupled to a surface of substrate 502.

Substrate 502 may be formed of any suitable substrate such as a portion of a BGA or PGA package. In accordance with the illustrate embodiment, substrate 502 includes connections 510 for Vcc, connections 512 for ground, connections 514 to circuit 508, and connections 516 to provide electrical contact between device 506, 507 and circuit 508.

Similarly, substrate 504 may be formed of any suitable material and in accordance with one aspect of the invention, substrate 504 is part of a computing system motherboard and includes device 506, 507 circuit 508, and waveguides 518. Devices 506, circuit 508, and waveguides 518, may includes any combination of optoelectronic devices, corresponding circuits, and optical waveguide materials described herein. For example, device 506 may be a light emitting device, device 507 may be a light detecting device, and circuit 508 may include suitable architecture to function as an amplifier for device 507 and a driver for device 506.

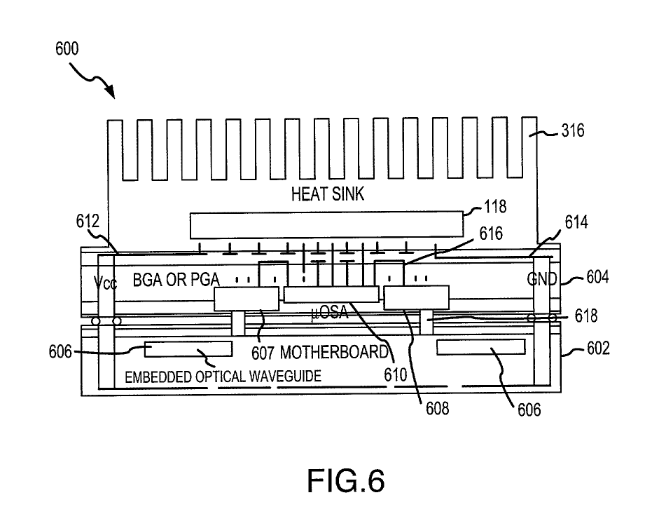

FIG. 6 illustrates yet another system 600, which includes a first substrate 602 having optical interconnects 606 and a second substrate 604 having optoelectronic devices 607 and 608 and a microelectronic circuit 610. System 600 is similar to system 500, except that devices 607, 608 and circuit 610 are coupled to or embedded in substrate 604 rather than substrate 602.

Substrate 604 includes Vcc connections 612, ground connection 614, and electrical connections 616 for providing electrical connection between circuit 610 and one or more devices 607, 608. Substrate 604 may comprise any suitable material such as packaging material typically used to form BGA or PGA device packages.

Substrate 602 includes optical interconnects 606, which may comprise any of the materials described above in connection with guides 408, illustrated in FIG. 4. Further, guides 606 are coupled to guides 618 using any of the techniques described above for coupling guides 408 to guides 420.

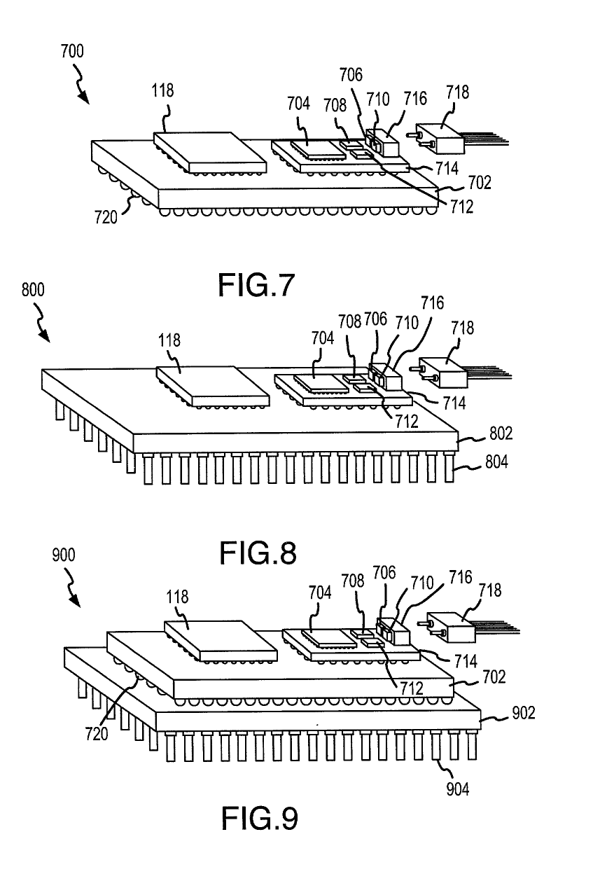

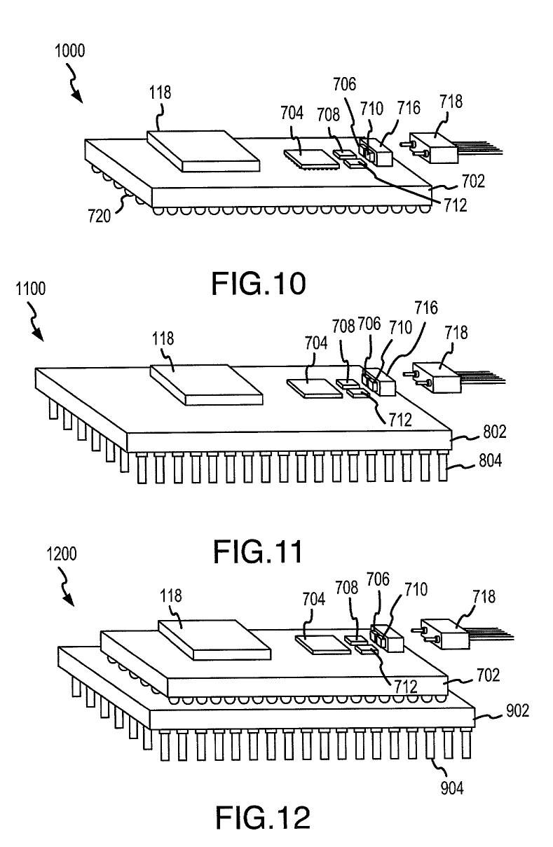

FIGS. 7-12 illustrate additional systems in accordance with the present invention, wherein the microprocessor and the optoelectronic devices are mounted, either directly or via another substrate, to the same side of a substrate. More specifically, FIGS. 7-9 illustrate systems in which the microprocessor and the optoelectronic devices are each mounted to separate substrate and the separate substrates are coupled to a base substrate and FIGS. 10-12 illustrate systems in which the microprocessor and the optoelectronic devices are coupled to the same substrate.

System 700, illustrated in FIG. 7, includes a first substrate 702 coupled to microprocessor 118 and a second substrate 714 coupled to first substrate 702 and a serialize/deserialize circuit 704, an array of light emitting devices 706, a driver circuit 708, an array of light detecting devices 710, and a transimpedance and limit amplifier circuit 712. Substrates 702 and 704 may include any suitable material and in accordance with an exemplary embodiment of the invention include printed circuit board material such as FR-4 to allow electrical coupling between devices and other substrates coupled to the respective substrates.

In the illustrated embodiment, microprocessor 118 and substrate 714 are coupled to base substrate 702 using solder bump techniques such as C4 bump technology. Devices 704-712 may be coupled to substrate 714 using any suitable technique and are preferably coupled to substrate 714 using C4 or wire bond techniques. Substrate 714 includes conductive traces to couple circuits 708 and 712 to devices 706 and 710. In addition, substrate 702 includes conductive bumps 720 to facilitate mechanical and/or electrical coupling of substrate 702 to another substrate such as a computing system motherboard or an Organic Land Grid Array (OLGA) substrate. In accordance with a further aspect of this embodiment, optoelectronic devices 706 and 710 preferably form part of a coupler 716, described in greater detail in application Ser. No. 10/056,757, entitled APPARATUS FOR COUPLING AN OPTOELECTRONIC DEVICE TO A FIBER OPTIC CABLE AND A MICROELECTRONIC DEVICE, A SYSTEM INCLUDING THE APPARATUS, AND A METHOD OF FORMING THE SAME and filed Jan. 23, 2002, to facilitate easy connection to a fiber ribbon cable 718.

System 800, illustrated in FIG. 8 is similar to system 700, except that system 800 includes a substrate 802, rather than substrate 702, which includes pins 804 rather than conductive bumps 720 on substrate 702.

System 900 is the same as system 700, except than an additional substrate 902 is coupled to a lower surface of system 700. Substrate 902 may include any suitable material and in accordance with an exemplary aspect of the invention, substrate 902 includes an OLGA. Although illustrated with pins 904, substrate 902 may alternatively include conductive bumps as described above.

Systems 1000, 1100, and 1200, illustrated in FIGS. 10-12, are similar to systems 700, 800, and 900, respectively, except that systems 1000, 1100, and 1200 do not include substrate 714.

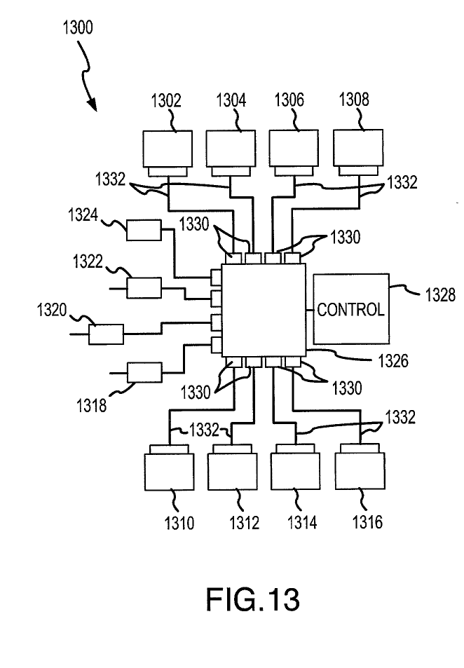

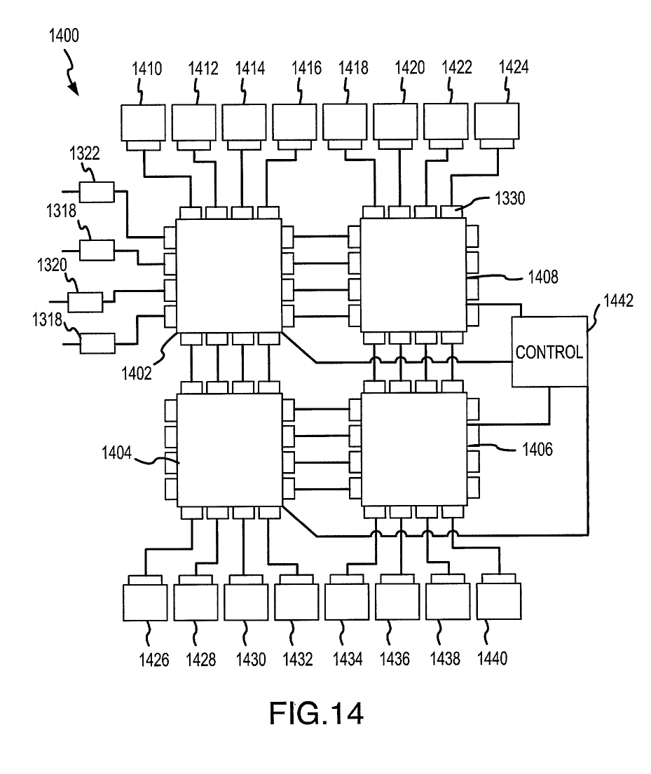

FIGS. 13 and 14 illustrate systems including multiple microprocessors coupled to a number of switches in accordance with exemplary embodiments of the invention.

System 1300 includes a plurality of microprocessors 1302-1308 coupled to a plurality of memory devices 1310-1316 and optionally to an InfiniBand port 1318, a graphics interface 1320, a hypertransport 1322, and/or another switch 1324, using a switch 1326 and a control circuit 1328 to route information between the components coupled thereto. In the illustrated embodiment, each component 1302-1326 is coupled to switch 1326 via an optical interconnect 1332 as described herein, which may use one or more waveguides to transmit the information. In the case of multiple waveguides, WDM or DWDM multiplexing and demultiplexing techniques may be used to transmit a plurality of wavelengths over a fewer number of waveguides.

In accordance with one aspect of the invention, switch 1326 is an electronic switch, and information is routed between the various components by converting optical information into electrical signals at devices 1330, such that switch 1326 can electrically process the information and then devices 1330 convert the information back to optical format for transmission to the selected component(s). In accordance with another embodiment of the invention, switch 1326 is an optical switch, in which case, devices 1330 are not required.

System 1400 is similar to system 1300, except system 1400 includes a plurality of switches 1402-1408 coupled to a plurality of microprocessors 1410-1424, a plurality of memory devices 1428-1440, and components 1318-1322. In the illustrated embodiment, switches 1402-1408 are electrical switches and are coupled to a single controller 1442; however, optical switches could be used in accordance with the present invention.

While the present invention is set forth herein in the context of the appended drawing figures, it should be appreciated that the invention is not limited to the specific form shown. For example, although the invention is conveniently described in connection with optical interconnects, the invention is not so limited. Various electrical interconnect using serial processing techniques may be employed in certain embodiments of the invention. Various other modifications, variations, and enhancements in the design and arrangement of the method and apparatus set forth herein, may be made without departing from the spirit and scope of the present invention.

We claim:

1. A system for transmitting information between a plurality of microelectronic devices, the system comprising:
a microelectronic device; and
an optical sub assembly coupled to the microelectronic device, the optical sub assembly comprising a first portion including a first optoelectronic device and a first corresponding circuit configured to convert electrical signals to optical signals and a second portion including a second optoelectronic device and a second corresponding circuit configured to convert optical signals to electrical signals, wherein the first portion and the second portion are coupled to a substrate.

2. The system of claim 1, further comprising a multiplexing circuit coupled to the first portion and the substrate and a demultiplexing circuit coupled to the second portion and the substrate.

3. The system of claim 1, further comprising a plurality of microelectronic devices.

4. The system of claim 4, wherein at least one of the plurality of microelectronic devices comprises a microprocessor.

5. The system of claim 1, further comprising an optical multiplexing device and an optical demultiplexing device.

6. The system of claim 1, wherein the first portion comprises an array of lasers.

7. The system of claim 1, wherein the second portion comprises an array of photodetectors.

8. The system of claim 1, further comprising a first optical connector coupled to the first portion and a second optical connector coupled to the second portion.

9. A system for transmitting information to a microelectronic device, the system comprising:
a first substrate;
a microelectronic device coupled to the first substrate;
an optical sub assembly coupled to the first substrate; and
a waveguide coupled to the optical sub assembly.

10. The system of claim 9, wherein the optical sub assembly and the microelectronic device are coupled to the same surface of the first substrate.

11. The system of claim 9, wherein the first substrate includes electrical connectors for coupling the microelectronic device to the optical sub assembly.

12. The system of claim 9, wherein the optical sub assembly includes an optoelectronic device and a corresponding circuit.

13. The system of claim 12, wherein the optoelectronic device comprises a laser and the corresponding circuit comprises a driver.

14. The system of claim 12, wherein the optoelectronic device comprises a photodetector and the corresponding circuit comprises a transimpedance amplifier and a limit amplifier.

15. The system of claim 9, further comprising a second substrate configured to receive the first substrate.

16. The system of claim 15, wherein the second substrate includes an optical waveguide.

17. The system of claim 15, wherein the second substrate includes electrical connectors configured to electrically couple to portions of the first substrate.

18. The system of claim 9, wherein the first substrate comprises a material selected from the group consisting of ball grid array package, pin grid array package, and plug-in board with an edge connector.

19. A system for transmitting information between a plurality of microelectronic devices, the system comprising:
a first substrate;
a microelectronic device coupled to the first substrate; and
a second substrate, the second substrate including an optoelectronic device, a corresponding circuit, and an optical waveguide optically coupled to the optoelectronic device.

20. The system of claim 19, wherein the first substrate includes electrical connectors for coupling the optoelectronic device and the corresponding circuit.

21. The system of claim 19, wherein the first substrate includes electrical connectors for coupling the microelectronic device to the corresponding circuit.

22. The system of claim 19, wherein the optical waveguide is embedded within the second substrate.

23. The system of claim 19, wherein the optoelectronic device and the corresponding circuit are embedded within the second substrate.

24. A system for transmitting information comprising:
a first substrate having an optoelectronic device and a corresponding circuit embedded within the first substrate; and
a second substrate electrically and mechanically coupled to the first substrate, the second substrate comprising an optical waveguide.

25. The system of claim 24, further comprising a microelectronic device coupled to the first substrate.

26. The system of claim 24, wherein the first substrate includes electrical connectors for coupling the optoelectronic device to the corresponding circuit.

27. The system of claim 24, wherein the first substrate includes electrical connectors configured to couple a microelectronic device to the second substrate and to the corresponding circuit.

28. The system of claim 24, wherein the optoelectronic device comprises a photodetector.

29. The system of claim 24, wherein the optoelectronic device comprises a laser.

30. A system for transmitting information, the system comprising:
a first substrate;
a microprocessor coupled to the first substrate;
a serialize/deserialize circuit coupled to the first substrate and the microprocessor;
a driver circuit coupled to the first substrate;
an array of light emitting devices coupled to the driver;
an amplifier circuit coupled to the substrate;
an array of light detecting devices coupled to the amplifier and the substrate; and
at least one waveguide coupled to the array of light detecting devices and the array of light emitting devices.

31. The system of claim 30, further comprising a second substrate coupled to the first substrate and interposed between the first substrate and the array of light emitting devices.

32. The system of claim 30, further comprising a third substrate coupled to the first substrate.

33. A system for transmitting information between a plurality of microelectronic devices, the system comprising:
a plurality of microprocessors; and
a switch optically coupled to the plurality of microprocessor.

34. The system of claim 33, further comprising a plurality of optical sub assemblies coupled to the switch and configured to convert information transmitted between the plurality of microprocessors and the switch between optical and electrical information.

35. The system of claim 33, further comprising a plurality of switches coupled together.

36. The system of claim 33, further comprising a plurality of memory devices coupled to the switch.

37. A system for transmitting information between a plurality of microelectronic devices comprising:
a microelectronic device;
a serial transmit device proximate the microelectronic device;
a serial receive device proximate the microelectronic device; and
a second microelectronic device coupled to at least one of the serial receive device and the serial transmit device.

38. A method of transmitting information between a plurality of microelectronic devices, comprising the steps of:
placing a first microelectronic device adjacent an optical subassembly, transmitting a plurality of signals from said first microelectronic device to said optical subassembly in N parallel paths,
multiplexing said plurality of signals, thereby reducing the number of parallel paths to N/K, where K is the multiplex reduction factor,
converting the signals on said N/K parallel paths to optical signals, and
propagating said optical signals through a waveguide to a second microelectronic device positioned distant from said optical subassembly.

39. A method as in claim 38, wherein the adjacent placing of the first microelectronic device and the optical subassembly is on the same substrate.

40. A method as in claim 38 wherein the propagating of optical signals is at K times the frequency of the transmission of said signals from said first microelectronic device to said optical subassembly.

41. A method of receiving optical information in an optical subassembly from a first microelectronic device positioned distant from said optical assembly, comprising the steps of:
detecting the optical information with N/K detectors, N/K being the number of parallel paths through which the information was propagated,
converting the optical information to electrical information,
demultiplexing the electrical information, thereby increasing the number of parallel paths to N,
placing a second microelectronic device adjacent said optical subassembly, and
transmitting the signal on the N parallel paths to the second microelectronic device.

42. A method as in claim 41, wherein the adjacent placing of the second microelectronic device and the optical subassembly is on the same substrate.

43. A method of transmitting information between a plurality of microelectronic devices, comprising the steps of:
placing a first microelectronic device adjacent an optical subassembly,
transmitting a plurality of signals from said first microelectronic device to said optical subassembly in N parallel paths,
multiplexing said plurality of signals, thereby reducing the number of parallel paths to N/K, where K is the multiplex reduction factor,
converting the signals on said N/K parallel paths to optical signals,
multiplexing said optical signals to further reduce the number of parallel paths to less than N/K, and
propagating said multiplexed optical signals through a waveguide to a second microelectronic device positioned distant from said optical subassembly.

44. A method of transmitting information between a plurality of microelectronic devices, as in claim 43, wherein the multiplexing of said optical signals reduces the number of paths to 1.

45. A method as in claim 43, wherein the adjacent placing of the first microelectronic device and the optical subassembly is on the same substrate.

46. A method of receiving optical information in an optical subassembly from a first microelectronic device positioned distant from said optical assembly, comprising the steps of:
demultiplexing the optical information to increase the number of parallel paths to N/K,
detecting the optical information with N/K detectors,
converting the optical information to electrical information,
demultiplexing the electrical information, thereby increasing the number of parallel paths to N,
placing a second microelectronic device adjacent said optical subassembly, and
transmitting the signal on the N parallel paths to the second microelectronic device.

47. A method as in claim 46, wherein the adjacent placing of the second microelectronic device and the optical subassembly is on the same substrate.
